(19) United States
(12) Patent Application Publication
(10) Pub. No.: US 2016/0097526 A1
(43) Pub. Date: Apr. 7, 2016

(54) ILLUMINATED ADHESIVE COVER

(71) Applicants: Richard Walkup, San Jose, CA (US); Stephen P. Oster, Auburn, CA (US)

(72) Inventors: Richard Walkup, San Jose, CA (US); Stephen P. Oster, Auburn, CA (US)

(21) Appl. No.: 14/875,621

(22) Filed: Oct. 5, 2015

Related U.S. Application Data
(60) Provisional application No. 62/061,001, filed on Oct. 7, 2014.

(51) Int. Cl. F21V 33/00; F21V 23/06; F21V 3/00; H05K 5/02

(52) U.S. Cl. CPC F21V 33/0052; H05K 5/0243; F21V 23/06; F21V 3/00; F21Y 2101/02; F21W 2121/00

(57) ABSTRACT

An adhesive cover for an electronic device includes an adhesive sheet, a transparent outside cover sheet and an illuminator. The adhesive sheet is for mounting on a cover or casing of the electronic device. The illuminator illuminates a media sheet located between the adhesive sheet and the transparent outside cover sheet.

### BACKGROUND

The casing and covers of portable electronic devices such as laptops, tablets and portable phones can be decorated using adhesive covers, called skins, that adhere to the casing or covers. The skins can be made from a variety of materials such as vinyl or plastic. The use of decorative skins allows personalization of the appearance of personal electronic devices as well as allows the user to make a statement about what is important to the user or what the user would like to communicate.

### BRIEF DESCRIPTION OF THE DRAWINGS

FIG. 1 shows an illuminated adhesive cover mounted on a case of a laptop computer in accordance with an implementation.

FIG. 2 shows an illuminated adhesive cover mounted on a back of a portable phone in accordance with an implementation.

FIG. 3 shows an illuminated adhesive cover mounted on a front of a portable phone in accordance with an implementation.

FIG. 4 shows an illuminated adhesive cover mounted on a back of a tablet computing device in accordance with an implementation.

FIG. 5 shows an illuminated adhesive cover mounted on a front of a tablet computing device in accordance with an implementation.

FIG. 6 is a simplified block diagram of a top view of an electroluminescent (EL) illuminated cover in accordance with an implementation.

FIG. 7 is a simplified block diagram of a side view of the electroluminescent illuminated cover shown in FIG. 1 in accordance with an implementation.

FIG. 8 is a simplified block diagram of a top view of a light emitting diode (LED) illuminated cover in accordance with an implementation.

FIG. 9 is a simplified block diagram of a side view of the LED illuminated cover shown in FIG. 8 in accordance with an implementation.

FIG. 10 is a simplified block diagram of another side view of the LED illuminated cover shown in FIG. 8 in accordance with an implementation.

FIG. 11, FIG. 12, FIG. 13 and FIG. 14 show additional embodiments.

### DESCRIPTION OF THE EMBODIMENT

In accordance with various implementations described herein, adhesive covers for portable electronic devices such as mobile phones, tablets and laptops, are illuminated to allow for greater options to personalize appearance of the portable electronic devices.

For example, the adhesive covers are skins that include a flexible adhesive backed sheet and are illuminated by light powered, for example, by an electronic device on which the adhesive cover is placed. Alternatively, the light can be powered by a battery.

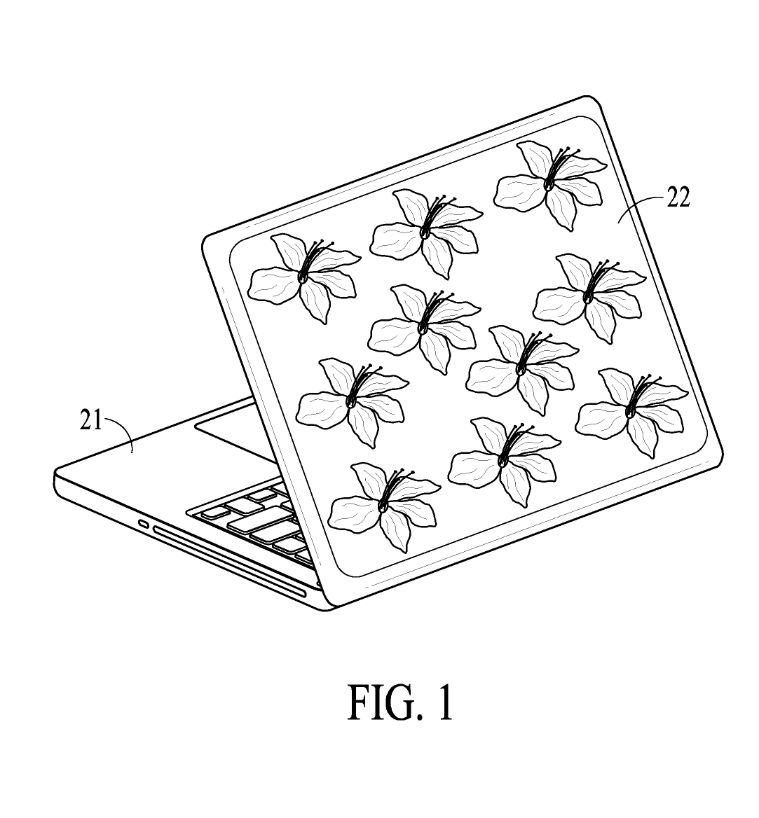

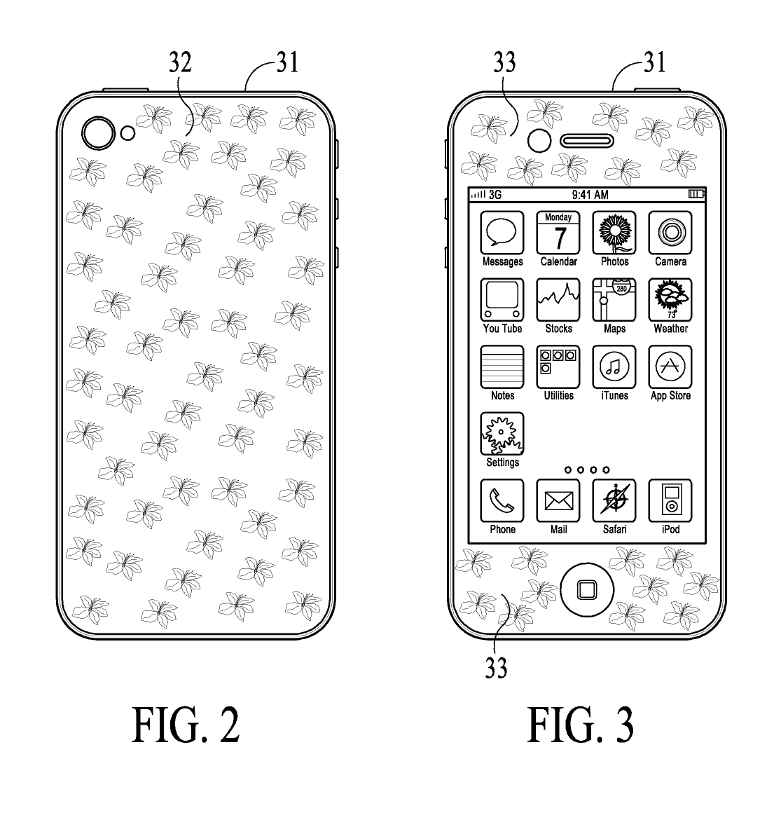

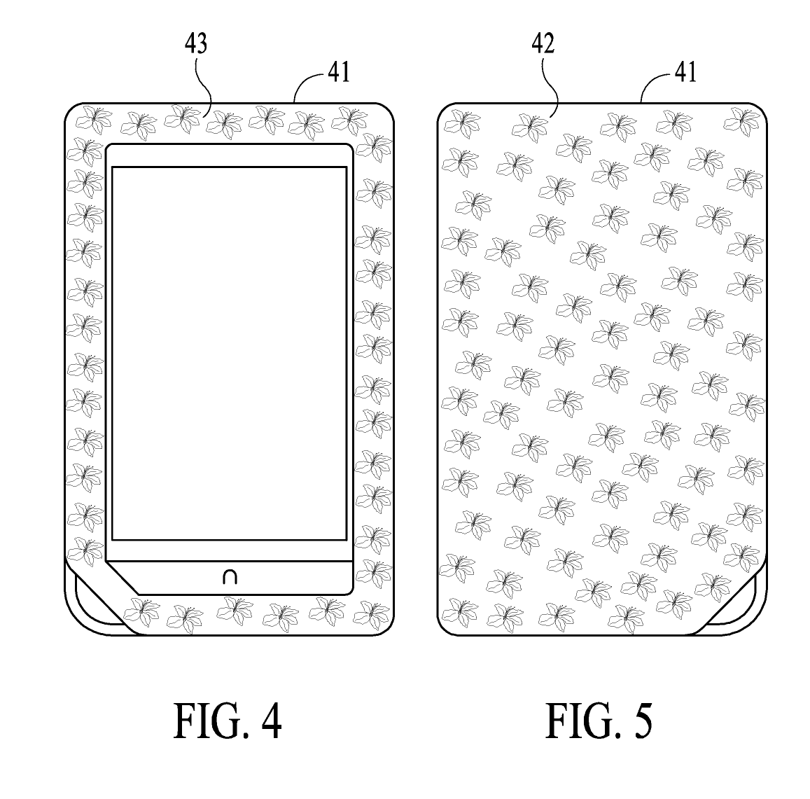

For example, FIG. 1 shows an illuminated adhesive cover 22 mounted on a case or cover of a laptop computer 21. FIG. 2 shows an illuminated adhesive cover 33 mounted on a back of a portable phone 31. FIG. 3 shows a front illuminated skin portion 33 mounted on a front of portable phone 31. FIG. 4 shows an illuminated adhesive cover 43 mounted on a back of a tablet computing device 41. FIG. 5 shows a front illuminated skin portion 43 mounted on a front of tablet computing device 41.

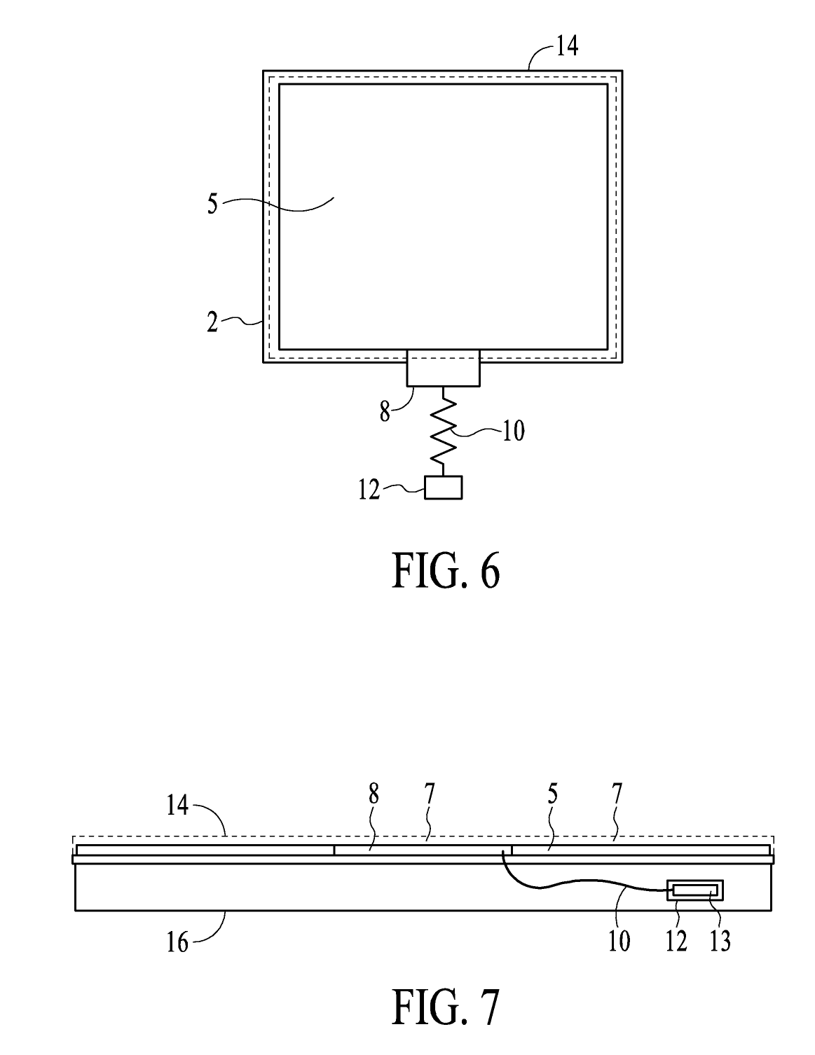

In one implementation, electroluminescent light is used for illumination. For example, FIG. 6 shows an implementation where an adhesive sheet 2 is composed of thin flexible plastic with adhesive on the underside. The adhesive enables adhesive sheet 2 to stick securely to a case or cover of a target electronic device, such as a laptop computer, tablet computing device or portable phone. On top of adhesive sheet 2 is placed an electroluminescent (EL) sheet 5 that serves as an illuminator. For example, EL sheet 5 is approximately one millimeter (mm) thick is placed. A thin transparent plastic cover sheet 14 is placed over EL sheet 5. A gap 7 (shown in FIG. 7) is left between EL sheet 5 and transparent plastic cover sheet 14. For example, gap 7 is less than 1 millimeter (mm) in width, just slightly wider than a typical paper thickness. Gap 7 is provided so that a translucent media sheet containing a graphic, a photo, or other illustration can be placed between EL sheet 5 and transparent plastic cover sheet 14. The translucent media sheet is illuminated by the backlight from EL sheet 5. Alternative to providing gap 7, a translucent media sheet may be permanently mounted between EL sheet 5 and transparent plastic cover sheet 14.

Driver electronics 8 drive electroluminescent lighting within EL sheet 5. Driver electronics 8 is connected by flat wiring traces to EL sheet 5.

Cable 10 supplies DC voltage to driver electronics 8. Cable 10 is implemented using, for example, small gauge wire such as AWG 24. For example, cable 10 includes two conductors in a harness that is robust so that friction in contact with other objects will not readily damage it. For example, cable 10 is in the form of a coil that when pulled on will expand to a length sufficient to enable connection to a port of the target electronic device. For example the port may be a universal serial bus (USB) port or some any port that is able to supply power to driver electronics 8.

Depending on the physical geometry of the target electronic device, the port may be a very short distance from driver 8. Alternatively, the port may be on a separate section of casing of the target electronic device, such as may occur when the target electronic device is a laptop computer where adhesive sheet 2 is mounted on the back of casing for a display and the port is located on casing that contains a keyboard. For example, cable 10 when coiled is short enough to plug into a port positioned close to driver electronics 8, minimizing extra length, yet cable 10 is able to extend when uncoiled to reach a port located a distance away from driver electronics 8. Alternatively, cable 10 can be custom sized dependent upon the configuration of the target electronic device.

Connector 12 is a connector that matches the port of the target electronic device. For example, connector 12 is a USB connector of type A, type B, mini type B 4, mini type B 5 B4, micro B or a connector of any other type that matches the port of the target electronic device. For example, connector 12 can be designed to protrude out from the target electronic device USB port as little as practical.

For example, connector 12 can include a female connector that acts as a replacement port for the port taken up by connector 12. This feature is especially useful for a target electronic device that, for example, has only have a single USB port. Since the only effect driver electronics 8 has on the port is to draw a relatively small amount of power, the female connector can electrically pass through signals directly between the port of the target electronic device and a peripheral connected to the female connector of connector 12 with no adverse affect on operation of driver electronics 8 or the peripheral, in most cases.

FIG. 7 shows a side view of adhesive sheet 2 adhering to a back side cover or casing of a target electronic device 16. For example, target electronic device 16 is a tablet or a portable phone. Alternatively, target device 16 is another type of computing device such as a laptop computer. Connector 12 is shown placed within a port of target electronic device 16. A female connector 13, within connector 12, is available as a replacement port for the port taken up by connector 12. Gap 7, not to scale, is shown visible between cover sheet 14 and EL sheet 5. In FIG. 7, gap 7 is shown wider than in practice for illustrative purposes. An uncoiled version of cable 10 is shown connecting connector 12 to driver electronics 8.

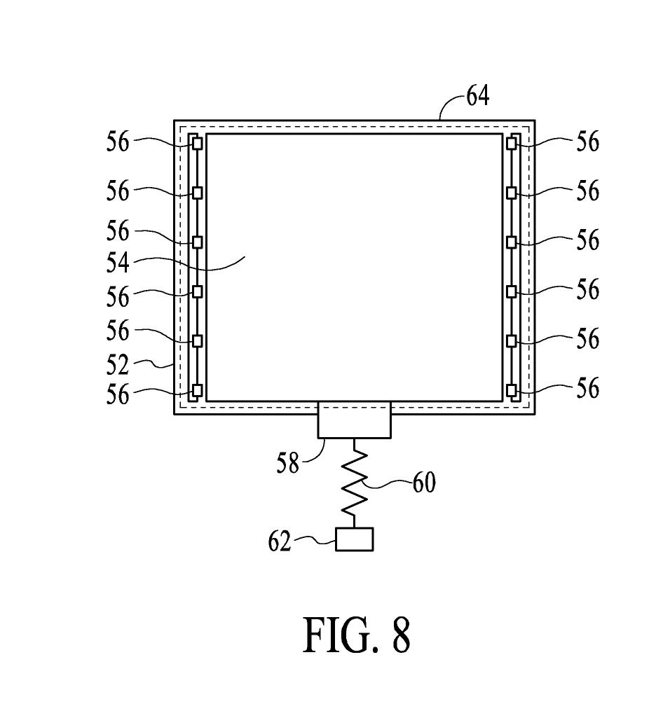

In another implementation, light from light emitting diodes (LEDs) is used for illumination. For example, FIG. 8 shows an implementation where an adhesive sheet 52 is composed of thin flexible plastic with adhesive on the underside. The adhesive enables adhesive sheet 52 to stick securely to a case or cover of a target electronic device, such as a laptop computer, tablet computing device or portable phone.

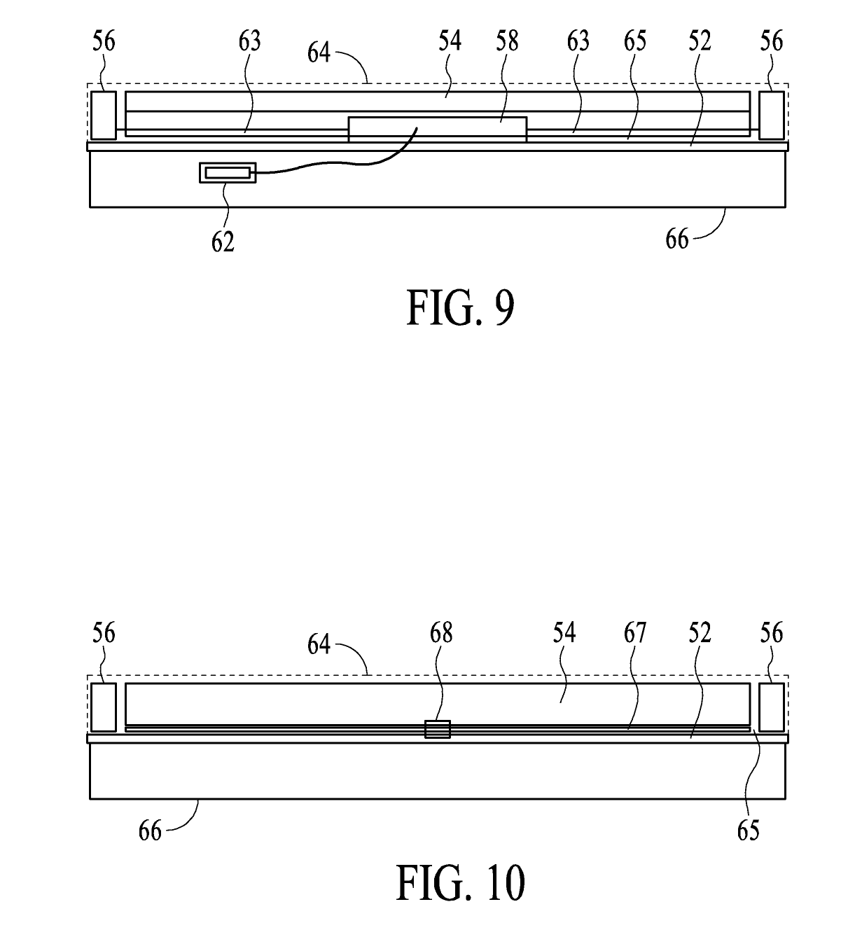

On top of adhesive sheet 52 is placed a light dispersing sheet 54 made of, for example, transparent or translucent plastic approximately 2 mm thick. There is a gap 65 (shown in FIG. 9) between sheet 54 and adhesive sheet 52. For example, gap 65 is just slightly wider than a typical paper thickness. Gap 65 is provided so that a media sheet containing a graphic, a photo, or other design or message can be placed under adhesive sheet 52 and be illuminated from above by light transmitted through light dispersing sheet 54.

LED edge lighting arrays 56 are placed along opposing edges of light dispersing sheet 54. While FIG. 8 shows LED edge lighting arrays 56 located on two sides of light dispersing sheet 54, for smaller display screens that are, for example, less than three or four inches wide, placing LED edge lighting arrays 56 on only one side of light dispersing sheet 54 provides sufficient illumination for many applications.

For example, each of LED edge lighting arrays 56 consists of a printed circuit board with LEDs placed along its length so that light emitted from the LEDs is directed into an adjacent edge of light dispersing sheet 54.

For example, light dispersing sheet 54 is composed of acrylic or other plastic designed to both transmit and disperse the light from LED edge lighting arrays 56 evenly throughout the area of light dispersing sheet 54. The combination of LED edge lighting arrays 56 and light dispersing sheet 54 serve as an illuminator.

Driver electronics 58 drive LED edge lighting arrays 56. Driver electronics 58 is connected by flat wiring traces to LED edge lighting arrays 56.

Cable 60 supplies DC voltage to driver electronics 58. Cable 60 is implemented using, for example, small gauge wire such as AWG 24. For example, cable 60 includes two conductors in a harness that is robust so that friction in contact with other objects will not readily damage it. For example, cable 60 is in the form of a coil that when pulled on will expand to a length sufficient to enable connection to a port of the target electronic device. For example the port may be a universal serial bus (USB) port or some any port that is able to supply power to driver electronics 58.

Depending on the physical geometry of the target electronic device, the port may be a very short distance from driver 58 or it may be on a separate section of casing of the target electronic device, such as may occur when the target electronic device is a laptop computer where adhesive sheet 52 is mounted on the back of casing for a display and the port is located on casing that contains a keyboard. For example, cable 60 when coiled is short enough to plug into a port positioned close to driver electronics 58, minimizing extra length, yet be able to extend when uncoiled to reach a port located a distance away from driver electronics 8. Alternatively, cable 60 can be custom sized dependent upon the configuration of the target electronic device.

Connector 62 is a connector that matches the port of the target electronic device, for example, connector 62 is a USB connector of type A, type B, mini type B 4, mini type B 5 B4, micro B or a connector of any other type that matches the port of the target electronic device, depending on the target electronic device. For example, connector 62 can be designed to protrude out from the target electronic device USB port as little as practical. For example connector 62 can include a female connector that acts as a replacement port for the port taken up by connector 62.

A covering material 64 is, for example, a protective, thin, partially-transparent cover placed over light dispersing sheet 54, LED edge lighting arrays 56, and driver electronics 58. Covering material 64 functions to protect, hide and hold together the internal components. For example, covering material 64 will be opaque along each edge where it covers LED edge lighting arrays 56, driver electronics 58, and overlaps with underlying adhesive sheet 52. A portion of covering material 64 that is over the top of plastic sheets 54 is transparent. Cover sheet 64 is composed of, for example, a type of plastic that resists scratches and scuffs while maintaining clarity and transparency.

FIG. 9 shows a side view of adhesive sheet 52 adhering to a back side of a target electronic device 66. For example, target electronic device 66 is a tablet or a portable phone. Alternatively, target electronic device 66 is another type of computing device such as a laptop computer. Connector 62 is shown placed within a port of target electronic device 66. A partially uncoiled version of cable 60 is shown connecting connector 62 to driver electronics 58.

Wires 63 extend from driver electronics 8 to each of LED edge lighting arrays 6. Wires 63 provide a DC current through LEDs in LED edge lighting arrays 56.

Gap 65 is shown visible between cover sheet 64 and underlying adhesive sheet 52. Into gap 15 a user can place a photo, graphic, or other media sheet of approximately standard paper thickness. The media sheet, when placed underneath light dispersing sheet 54 is visible through sheet 54. For example, Gap 65 is not accessible from sides of light dispersing sheet 54 where driver electronics 58 or LED edge lighting arrays 56 are located

FIG. 10 shows a side view opposite a side on which driver electronics is located. Thin flexible adhesive sheet 52 is shown adhering to target electronic device 66 or a cover for target electronic device 66.

Gap 65 is accessible from the side shown in FIG. 10. A media sheet 67 containing for example, a photo, a design, a message or some other graphic has been slipped into gap 65 for illumination by LEDs in LED edge lighting arrays 56. A width of gap 65 is selected to be just slightly wider than a width of media sheet 67. An optional latch or other catching device 68 is used, for example, to prevent media sheet 67 from slipping out of gap 65 during usage of electronic device 66.

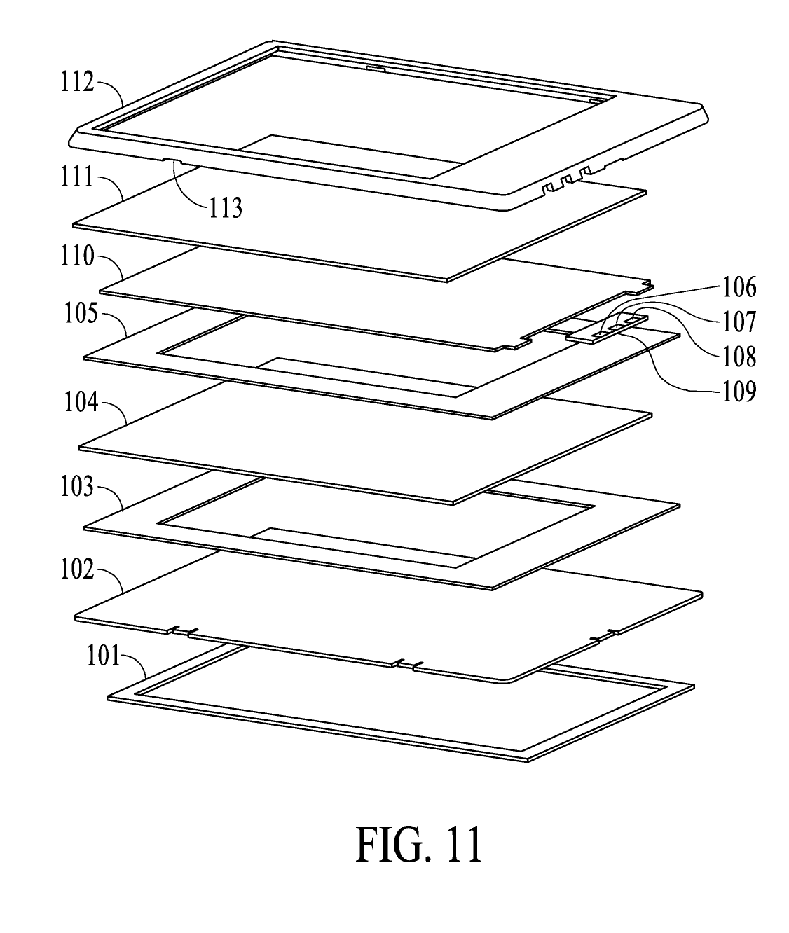

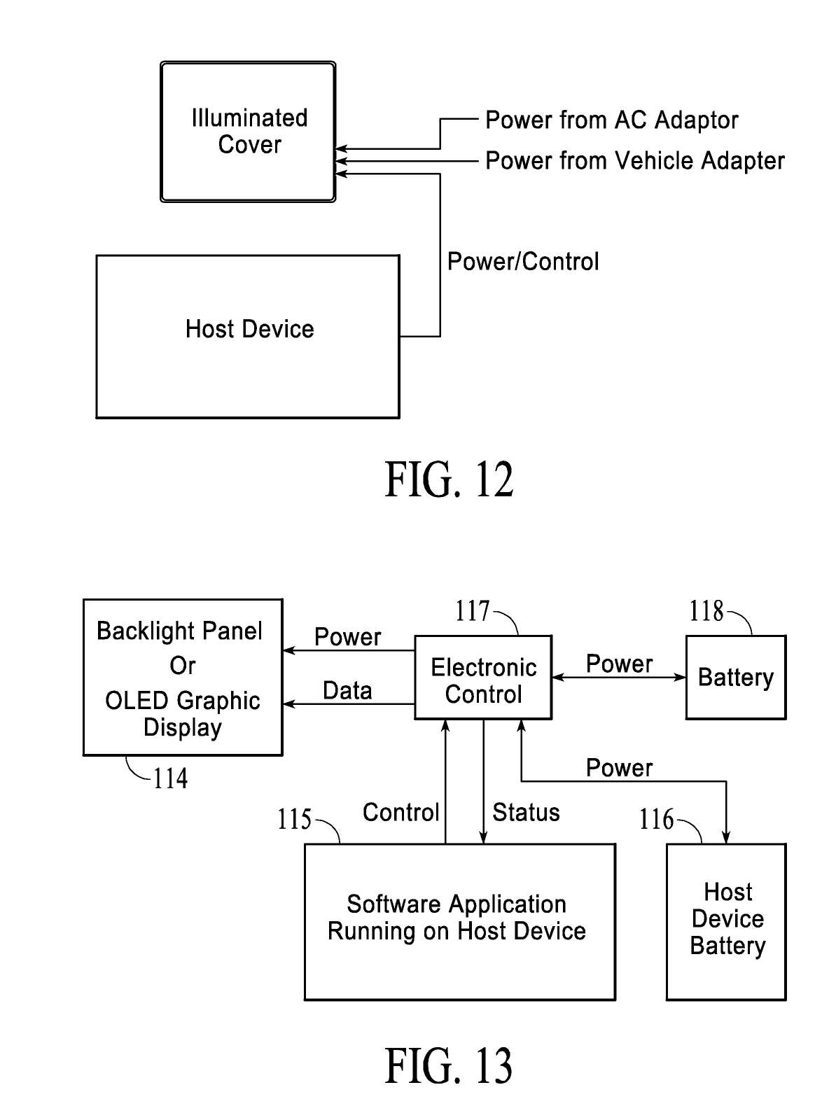

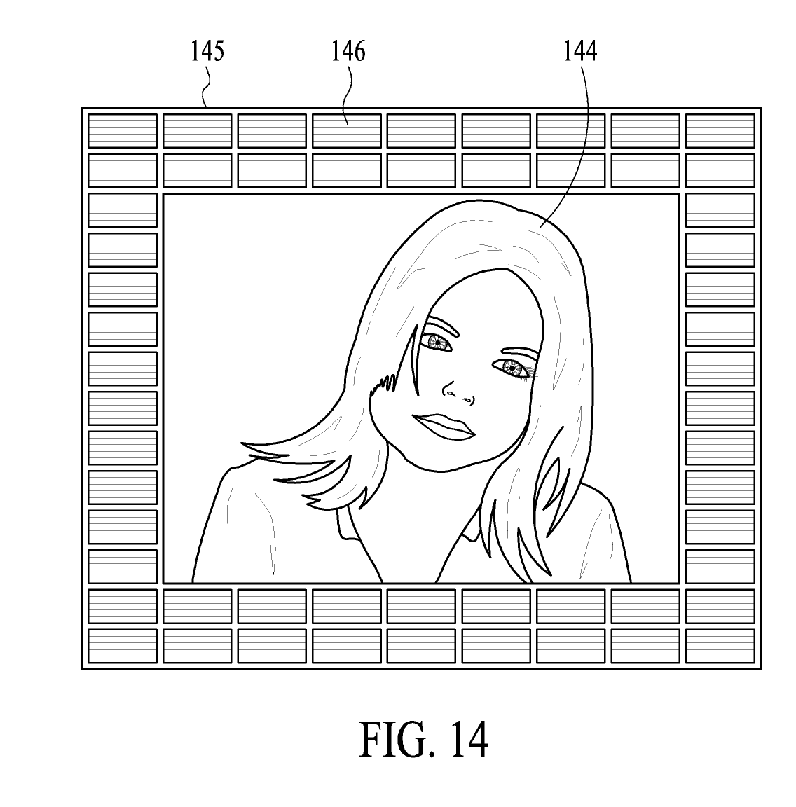

In one implementation, a fiber optic panel illuminated by light-emitting diodes (LEDs) is used for illumination. For example, FIG. 11 shows an implementation where an adhesive sheet 101 is composed of thin flexible plastic with adhesive on both sides (all adhesive sheets in this description are double-sided). On top of adhesive sheet 101 is placed the lower half of plastic frame 102. Adhesive sheet enables the adhesive cover to attach firmly to a case or the cover of a target electronic device, such as a laptop computer, tablet computing device or portable phone. Another adhesive sheet 103 is placed on top of frame lower half 102. On top of adhesive sheet 103, a flat, very thin battery 104 is placed. Battery 104 covers the area of frame lower half 102 and is intentionally as large in the Length×Width dimensions as possible in order to get the largest practical battery capacity. This enables the illuminated cover to be operated for a longer time, plus enables it to be used as a backup power source for the Host Device or another device. The battery is thin, 1 mm thick in the preferred embodiment, but could be thinner or thicker. Another adhesive sheet 105 is placed on top of battery 104. On top of adhesive sheet 105 is placed a flat, thin fiber optic panel 110 with LEDs that provides light. On one edge of fiber optic panel 110 a small electronic circuit board 109 is placed. Circuit board 109 contains all the electronics used to manage the illuminated cover. Circuit board 109 includes on/off and brightness control 106, mode control 107, micro USB socket 108, and may include a microcontroller to communicate with the Host device running a software application that can control functions of flat fiber panel 110 such as blinking, fading, brightness, etc. On top of fiber optic panel 110 a thin plastic, translucent media sheet 111 is placed that contains a graphic. Translucent media sheet 111 is illuminated by the backlight from fiber optic panel 110. Plastic top frame half 112 completes this embodiment. Top frame half 112 is placed over the top of the stack of all the previous components, and fastens to frame lower half 102 by four tabs placed along the long edges of lower frame half 102. The tabs interlock with corresponding features on upper frame half 112 to securely fasten frame upper half 112 to frame lower half 102 and keep the assembly together. Upper frame half 112 can be removed by inserting a small flat screwdriver blade into slots 113. All adhesive sheets can be made as shown in FIG. 11, or can have varying configurations. For example, some or all of them could be implemented as two or more individual strips placed alone two or more edges in each location they are needed. This would save material and result in lower cost.

Another option is to place a clear plastic sheet in between frame upper half 112 and graphic sheet 111 to act as a physical protection for graphic sheet 111. This would require additional adhesive material.

In another implementation, flat fiber optic panel 110 is replaced by a graphics display panel. This could be an LCD, TFT, or other commonly-used display. Or in the preferred embodiment of this implementation, a very thin organic LED graphics display (OLED) is used. To implement this, circuit board 109 includes additional circuitry such as a microcontroller that enables the circuit to communicate with an application (app) running on the host device to control the OLED display. The OLED display replaces both fiber optic panel 110 and graphic sheet 111. Instead of a backlit static graphic, the OLED display is capable of displaying anything the application on the host device sends to it via the electronic control board and connecting cable.

FIG. 12 shows how the illuminated cover receives power from various sources and connects to the host device. In FIG. 12, the illuminated cover is powered through its USB socket (FIG. 11 number 108). A standard USB cable that has a micro USB plug on one end and on the other a USB plug compatible with popular portable devices is used to charge the battery of the illuminated cover from the host device. The cable also enables an app running on the Host device to control the functioning of the flat-fiber backlight panel or the OLED graphic display. This ability enables the user to customize the operation of the illuminated cover as desired.

Yet another way to provide communication and control between the host device and the illuminated cover is to include wireless communication circuitry on circuit board 109 in FIG. 11. This could be WiFi, Bluetooth, or any other compatible wireless communication method. The preferred method is Bluetooth for small portable devices such as cell phones and tablets; WiFi for laptop PCs.

FIG. 13 shows in more detail the capability for the user to control functions through a software application 115 (app) running on the host device. App 115 sends commands to the electronic control circuit 117. This control included brightness, any special functions such as fading, flashing, etc., or data to panel 114 or to change the display for the embodiment using the OLED graphics display as panel 114. Electronic Control 117 in turn, provides power to the panel 114 and data or other control functions. Electronic Control 117 also provides power to Battery 118 and manages charging, or sources power from Battery 118 and provides it to the Host device (or any other device that is compatible) through the USB cable connection to charge Host Device Battery 116. This power management capability can be provided solely by a mechanical Mode switch on Electronic Control 117, by App 115, or by either. Software App 115 is written to be compatible with any popular Operating System used by any of the popular Host devices including Android, Windows, Linux, IOS, etc. App 115 will include a graphical user interface for the user to make menu, drop-down list box, or command button selections to completely control all functions of the illuminated cover.

The illuminated cover can also be powered through its micro USB socket by connecting any popular power source designed for charging portable devices such as cell phones and tablets. Power from any charging source, such as an AC adaptor or an adaptor using 12V from a motor vehicle, can be used to power up and charge the battery of the illuminated cover.

The connection between the illuminated cover and the Host device can also be used to transfer power from the battery of the illuminated cover to charge the host battery. The battery of the illuminated cover is a high-capacity battery and will have the ability to charge the batteries of small devices such as cell phones and tablets successfully, adding one more feature to the utility of the illuminated cover. In use, if the Host device needs power, the illuminated cover can be used as a backup source of power for the Host device or any other compatible device.

The electronic control board 109 shown in FIG. 11 will vary slightly in the various embodiments of the illuminated cover. For the embodiment using the fiber optic panel as the backlight source, electronic control board 109 will only control simple functions of the panel such as on/off, brightness, and flashing or fading. For the embodiment using the OLED graphics display in place of the backlight panel 110 and graphic sheet 111, electronic control board 109 will also include the ability to send data to the OLED display. This enables the user, using an application running on the host device, to change the display at any time desired. In all cases, the electronic control board 109 will manage charging the internal battery 104 using externally-supplied power, or delivering power from battery 104 to the host device or any external device.

Another possible embodiment of this invention is the use of photovoltaic panels to generate electricity from ambient light sources and charge battery 104 of FIG. 11. In this embodiment, frame upper half 112 could have wider edges all around, for example 1 inch in width. Frame 112 could be made of transparent plastic and photovoltaic cells matching the width of the edges of frame 112 could be positioned on the inside of the frame so that ambient light reaches the cells. This is shown conceptually in FIG. 14. The frame upper half 145 has all four edges much wider and using transparent clear plastic. PV cells are in an array 146 distributed around all four edges of frame upper half 145. The cells are connected to electronic control board 109 of FIG. 11, which would then manage the current generated by the photovoltaic cells and use it to power the adhesive cover and/or charge battery 104.

The foregoing discussion discloses and describes merely exemplary methods and embodiments. As will be understood by those familiar with the art, the disclosed subject matter may be embodied in other specific forms without departing from the spirit or characteristics thereof. Accordingly, the present disclosure is intended to be illustrative, but not limiting, of the scope of the invention, which is set forth in the following claims.

What is claimed is:

1. An adhesive cover for an electronic device, comprising:
an adhesive sheet for mounting on a cover or casing of the electronic device;
a transparent outside cover sheet;
a gap into which a media sheet can be placed, the gap being located between the adhesive sheet and the transparent outside cover sheet; and,
an illuminator that illuminates the media sheet so that the media sheet from outside the transparent outside cover sheet is illuminated.

2. An adhesive cover as in claim 1 wherein the illuminator is an electroluminescent sheet placed between the gap and the adhesive sheet, the illuminator providing back lighting for the media sheet.

3. An adhesive cover as in claim 1 wherein the illuminator is a light dispersing sheet illuminated by light emitting diodes, the light dispersing sheeting being located between the gap and the transparent outside cover sheet.

4. An adhesive cover as in claim 1 wherein power for the illuminator is obtained from a port of the electronic device.

5. An adhesive cover as in claim 1 additionally comprising:
a connector, for connecting to and obtaining power from a port of the electronic device.

6. An adhesive cover as in claim 1 additionally comprising:
a connector, for connecting to and obtaining power from a universal serial bus (USB) port of the electronic device.

7. An adhesive cover as in claim 1 additionally comprising:
a connector, for connecting to and obtaining power from a port of the electronic device, the connector including a female connector for allowing other peripheral devices to access the port.

8. A method for providing illuminated media on an electronic device, the method, comprising:
mounting an adhesive cover on a cover or casing of the electronic device, the adhesive cover including an adhesive sheet that sticks to the cover or the casing, a transparent outside cover sheet;
placing a media sheet between the adhesive sheet and the transparent outside cover sheet; and,
illuminating the media sheet with an illuminator.

9. A method as in claim 8 wherein illuminating the media sheet with an illuminator includes providing back lighting for the media sheet from an electroluminescent sheet placed over the adhesive sheet.

10. A method as in claim 8 wherein illuminating the media sheet with an illuminator includes dispersing light from light emitting diodes using dispersing sheeting located over the media sheet and under the transparent outside cover sheet.

11. A method as in claim 8 wherein illuminating the media sheet with an illuminator includes obtaining power from a port of the electronic device.

12. A method as in claim 8 wherein illuminating the media sheet with an illuminator includes obtaining power from a universal serial bus (USB) port of the electronic device.

13. An adhesive cover for an electronic device, comprising:
an adhesive sheet for mounting on a cover or casing of the electronic device;
a transparent outside cover sheet;
a media sheet placed located between the adhesive sheet and the transparent outside cover sheet; and,
an illuminator that illuminates the media sheet so that the media sheet from outside the transparent outside cover sheet is illuminated.

14. An adhesive cover as in claim 13 wherein the illuminator is an electroluminescent sheet placed between the media sheet and the adhesive sheet, the illuminator providing back lighting for the media sheet.

15. An adhesive cover as in claim 13 wherein the illuminator is a light dispersing sheet illuminated by light emitting diodes, the light dispersing sheeting being located between the media sheet and the transparent outside cover sheet.

16. An adhesive cover as in claim 13 wherein power for the illuminator is obtained from a port of the electronic device.

17. An adhesive cover as in claim 13 additionally comprising:
a connector, for connecting to and obtaining power from a port of the electronic device.

18. An adhesive cover as in claim 13 additionally comprising:
a connector, for connecting to and obtaining power from a universal serial bus (USB) port of the electronic device.

19. An adhesive cover as in claim 13 additionally comprising:
a connector, for connecting to and obtaining power from a port of the electronic device, the connector including a female connector for allowing other peripheral devices to access the port.

20. An adhesive cover for an electronic device, comprising:
an adhesive sheet for mounting on a cover or casing of the electronic device;
a transparent outside cover sheet; and,
a gap into which a media sheet can be placed, the gap being located between the adhesive sheet and the transparent outside cover sheet.
